(19) United States
(12) Patent Application Publication
(10) Pub. No.: US 2010/0078068 A1
(43) Pub. Date: Apr. 1, 2010

(54) SOLAR CELL WITH EMBEDDED ELECTRODE

(76) Inventor: Chin-Tien YANG, Hsinchu County (TW)

Correspondence Address: Muncy, Geissler, Olds & Lowe, PLLC, P.O. BOX 1364, FAIRFAX, VA, 22038-1364, US

(21) Appl. No.: 12/561,575

(22) Filed: Sep. 17, 2009

(30) Foreign Application Priority Data
Sep. 30, 2008 (TW) 097137418

(51) Int. Cl. H01L 31/00

(52) U.S. Cl. 136/256

(57) ABSTRACT

A solar cell includes a silicon substrate, an anti-reflection coating (ARC) layer, an embedded electrode and a back-side electrode. The silicon substrate has a front side and a back side. The silicon substrate has a P⁺ silicon layer near the back side, an N⁺ silicon layer near the front side and a

P-type silicon layer disposed between the P⁺ silicon layer and the N⁺ silicon layer. The ARC layer is formed on the front side of the silicon substrate. The embedded electrode penetrates through the ARC layer and the N⁺ silicon layer, projects out of the ARC layer, and is electrically connected to the N⁺ silicon layer and the P-type silicon layer. The back-side electrode is formed on the back side of the silicon substrate and electrically connected to the P⁺ silicon layer.

This application claims priority of No. 097137418 filed in Taiwan R.O.C. on Sep. 30, 2008 under 35 USC 119, the entire content of which is hereby incorporated by reference.

### BACKGROUND OF THE INVENTION

1. Field of the Invention

The invention relates to a solar cell with an embedded electrode.

2. Related Art

FIG. 1 is a top view showing a conventional solar cell. Referring to FIG. 1, the conventional solar cell includes a silicon substrate 110, an anti-reflection coating (ARC) layer 120 and two front-side main electrodes 150 and several front side sub-electrodes 160 disposed on the ARC layer 120. The ARC layer 120 is typically composed of silicon nitride, for example.

Although the front side sub-electrode must provide the function of collecting charges, the too-wide front side sub-electrode blocks the light ray from entering the silicon substrate so that the light quantum availability of the solar cell is decreased. However, the too-narrow front side sub-electrode increases the resistance to influence the efficiency of the solar cell. Thus, the number and the width of the front side sub-electrodes have to be optimized so that the light quantum availability can be optimized.

### SUMMARY OF THE INVENTION

It is therefore an object of the invention to provide a solar cell with embedded electrodes so that an opening area of a front side of the solar cell is enlarged, and the contact resistance between the electrode and the silicon substrate may be reduced.

To achieve the above-identified object, the invention provides a solar cell including a silicon substrate, an anti-reflection coating (ARC) layer, an embedded electrode and a back-side electrode. The silicon substrate has a front side and a back side. The silicon substrate has a P⁺ silicon layer near the back side, an N⁺ silicon layer near the front side and a P-type silicon layer disposed between the P⁺ silicon layer and the N⁺ silicon layer. The ARC layer is formed on the front side of the silicon substrate. The embedded electrode penetrates through the ARC layer and the N⁺ silicon layer, projects out of the ARC layer, and is electrically connected to the N⁺ silicon layer and the P-type silicon layer. The back-side electrode is formed on the back side of the silicon substrate and electrically connected to the P⁺ silicon layer.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a top view showing a conventional solar cell.

FIG. 2 is a top view showing a solar cell according to the invention.

FIG. 3 is a cross-sectional view taken along a line 3-3 of FIG. 2.

FIG. 4 is a cross-sectional view taken along a line 4-4 of FIG. 2.

FIG. 5 shows another example corresponding to the solar cell of FIG. 4.

FIGS. 6 to 10 show steps of forming embedded electrodes.

### DETAILED DESCRIPTION OF THE INVENTION

The present invention will be apparent from the following detailed description, which proceeds with reference to the accompanying drawings, wherein the same references relate to the same elements.

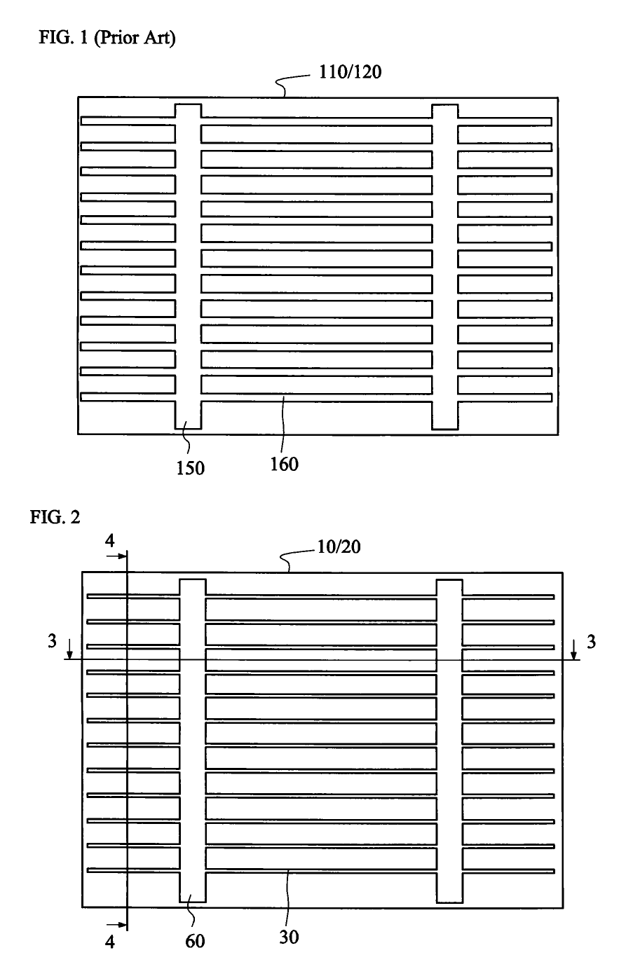

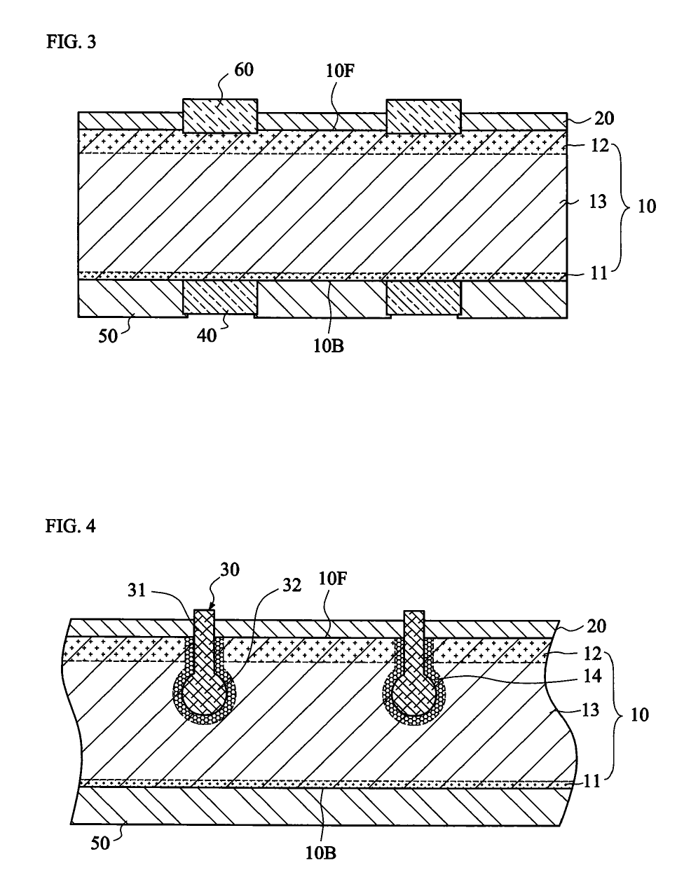

FIG. 2 is a top view showing a solar cell according to the invention. FIG. 3 is a cross-sectional view taken along a line 3-3 of FIG. 2. FIG. 4 is a cross-sectional view taken along a line 4-4 of FIG. 2. Referring to FIGS. 2 and 3, the solar cell of the invention includes a silicon substrate 10, an anti-reflection coating (ARC) layer 20, an embedded electrode 30 and a back-side electrode 40.

The silicon substrate 10 has a front side 10F and a back side 10B. As for the detailed structure, the silicon substrate 10 has a P⁺ silicon layer 11 near the back side 10B, an N⁺ silicon layer 12 near the front side 10F and a P-type silicon layer 13 disposed between the P⁺ silicon layer 11 and the N⁺ silicon layer 12. The P⁺ silicon layer 11, the N⁺ silicon layer 12 and the P-type silicon layer 13 may be formed by doping the silicon substrate, or may be formed by way of deposition or other methods.

The ARC layer 20 is formed on the front side 10F of the silicon substrate 10, and is usually made of silicon nitride. However, other materials may also be adopted, or the ARC layer may be composed of multiple layers.

One embedded electrode 30 or a plurality of embedded electrodes 30 may be formed. The embedded electrode 30 penetrates through the ARC layer 20 and the N⁺ silicon layer 12, projects out of the ARC layer 20, and is electrically connected to the N⁺ silicon layer 12 and the P-type silicon layer 13. In this example, the embedded electrode 30 is formed by a rectangular column portion 31 and a cylindrical portion 32 connected together. The embedded electrode 30 may be made of nickel, copper or silver. In this embodiment, the embedded electrode 30 may also be referred to as a finger electrode.

The back-side electrode 40 is formed on the back side 10B of the silicon substrate 10 and is electrically connected to the P⁺ silicon layer 11.

In addition, the solar cell may further include a back-side metal layer 50 and a front-side main electrode 60. The back-side metal layer 50 is usually made of aluminum. The back-side metal layer 50 is formed on the back side 10B of the silicon substrate 10. The front-side main electrode 60 is formed on the ARC layer 20 and is electrically connected to the N⁺ silicon layer 12 and the embedded electrode 30. The solar cell usually has two front-side main electrodes 60.

In addition, the silicon substrate 10 may further have an N⁺⁺ silicon section 14, which surrounds the embedded electrode 30 in order to decrease the contact resistance. The N⁺⁺ silicon section 14 may be formed by diffusing ions into the silicon substrate 10 through the embedded electrode 30. The doping concentration in the N⁺⁺ silicon section is higher than that in the N⁺ silicon layer.

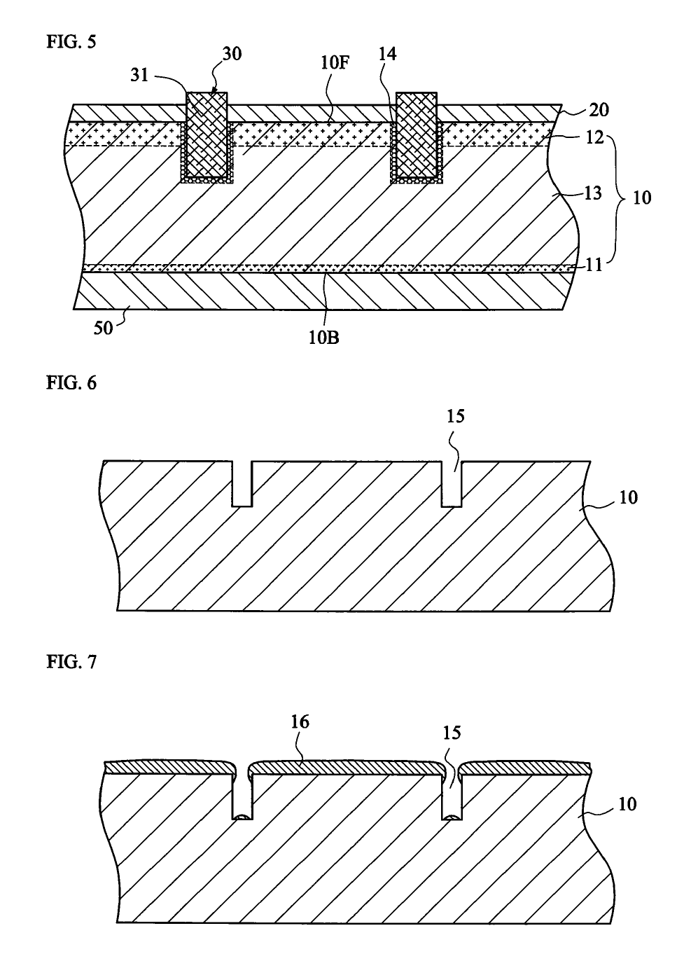

FIG. 5 shows another example corresponding to the solar cell of FIG. 4. As shown in FIG. 5, this example is similar to that of FIG. 4 except that the embedded electrode 30 only contains the rectangular column portion 31 and the efficiency of the solar cell still can be enhanced.

It is to be noted that the structure of the embedded electrode is applied to the front-side sub-electrode of the solar cell, and may also be applied to the front-side main electrode of the solar cell. In addition, the structure of the embedded electrode of the invention and the conventional structure of the front-side sub-electrode may coexist within the spirit of the invention.

On the other hand, the P⁺ silicon layer 11, the N⁺ silicon layer 12, the P-type silicon layer 13 and the N⁺⁺ silicon section 14 may be respectively replaced with an N⁺ silicon layer, a P⁺ silicon layer, an N-type silicon layer and a P⁺⁺ silicon section. Thus, the silicon substrate has an N⁺ silicon layer near the back side, a P⁺ silicon layer near the front side and an N-type silicon layer disposed between the N⁺ silicon layer and the P⁺ silicon layer. The front-side main electrode is electrically connected to the P⁺ silicon layer. The embedded electrode penetrates through the ARC layer and the P⁺ silicon layer, projects out of the ARC layer, and is electrically connected to the front-side main electrode, the P⁺ silicon layer and the N-type silicon layer. The back-side electrode is formed on the back side of the silicon substrate, and is electrically connected to the N⁺ silicon layer. The silicon substrate may further have a P⁺⁺ silicon section surrounding the embedded electrode.

FIGS. 6 to 10 show steps of forming embedded electrodes. The steps of forming the embedded electrodes will be described with reference to FIGS. 6 to 10.

First, as shown in FIG. 6, a groove 15 is formed on the silicon substrate 10 by way of, for example, etching or other processing. It is to be noted that an ARC layer (not shown) may also cover the upper surface of the silicon substrate 10.

Next, as shown in FIG. 7, an aluminum oxide or silicon nitride layer 16 is formed on the silicon substrate 10 and the groove 15 by way of sputtering. It is to be noted that a portion of the aluminum oxide or silicon nitride layer 16 is deposited on the bottom portion of the groove 15.

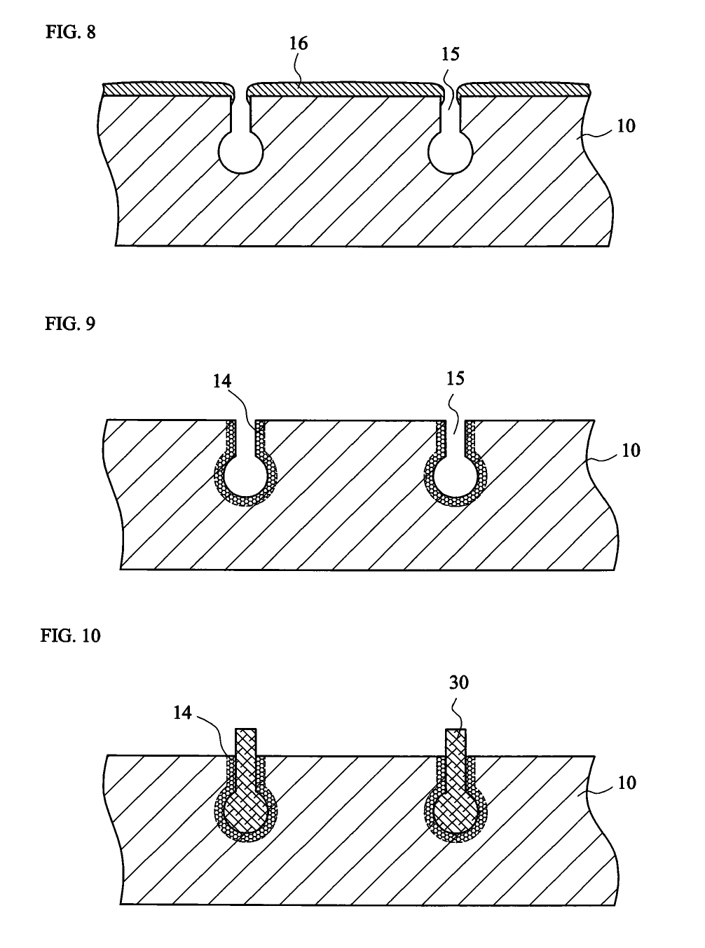

Then, as shown in FIG. 8, the groove 15 is etched by way of wet etching to enlarge the groove 15 and to form a hole at the bottom of the groove 15. The aluminum oxide or silicon nitride layer 16 serves as an etch-protection layer. The aluminum oxide or silicon nitride layer 16 deposited on the bottom of the groove 15 is removed when the bottom portion of the groove 15 is removed.

Next, as shown in FIG. 9, the aluminum oxide or silicon nitride layer 16 is removed, and the N⁺⁺ silicon section 14 is formed around the enlarged groove 15 by way of depositing, PoCl₃ doping, ion implanting, or spraying in conjunction with laser annealing.

Then, as shown in FIG. 10, the embedded electrode 30 composed of nickel, copper or silver is formed by way of plating.

Next, the steps of processing or forming the P⁺ silicon layer 11 or the N⁺ silicon layer 12 may be performed, for example.

According to the solar cell of the invention, the Ohmic contact relationship between the embedded electrode 30 and the silicon substrate may be improved and the contact resistance may be decreased such that the efficiency of the solar cell may be enhanced. On the other hand, the contact surface area between the embedded electrode 30 and the silicon substrate is relatively large, so the area of the rectangular column portion of the embedded electrode 30 occupied on the ARC layer can be effectively decreased. Thus, the shielding ratio of the embedded electrode 30 on the sunlight may be effectively reduced so that the efficiency of the solar cell may be further enhanced.

While the invention has been described by way of examples and in terms of preferred embodiments, it is to be understood that the invention is not limited thereto. To the contrary, it is intended to cover various modifications. Therefore, the scope of the appended claims should be accorded the broadest interpretation so as to encompass all such modifications.

What is claimed is:

1. A solar cell, comprising:
a silicon substrate having a front side, a back side, a P⁺ silicon layer near the back side, an N⁺ silicon layer near the front side and a P-type silicon layer disposed between the P⁺ silicon layer and the N⁺ silicon layer;
an anti-reflection coating (ARC) layer formed on the front side of the silicon substrate;
an embedded electrode, which penetrates through the ARC layer and the N⁺ silicon layer, projects out of the ARC layer, and is electrically connected to the N⁺ silicon layer and the P-type silicon layer; and
a back-side electrode formed on the back side of the silicon substrate and electrically connected to the P⁺ silicon layer.

2. The solar cell according to claim 1, further comprising a back-side metal layer formed on the back side of the silicon substrate.

3. The solar cell according to claim 2, wherein the silicon substrate further has an N⁺⁺ silicon section surrounding the embedded electrode.

4. The solar cell according to claim 2, wherein the back-side metal layer is made of aluminum.

5. The solar cell according to claim 2, wherein the embedded electrode is composed of a rectangular column portion and a cylindrical portion connected together.

6. The solar cell according to claim 2, further comprising:
a front-side main electrode formed on the ARC layer and electrically connected to the N⁺ silicon layer and the embedded electrode.

7. The solar cell according to claim 2, wherein the embedded electrode is made of nickel, copper or silver.

8. A solar cell, comprising:
a silicon substrate having a front side, a back side, an N⁺ silicon layer near the back side, a P⁺ silicon layer near the front side, and an N-type silicon layer disposed between the N⁺ silicon layer and the P⁺ silicon layer;
an anti-reflection coating (ARC) layer formed on the front side of the silicon substrate;
a front-side main electrode formed on the ARC layer and electrically connected to the P⁺ silicon layer;
an embedded electrode, which penetrates through the ARC layer and the P⁺ silicon layer, projects out of the ARC layer, and is electrically connected to the front-side main electrode, the P⁺ silicon layer and the N-type silicon layer; and
a back-side electrode formed on the back side of the silicon substrate and electrically connected to the N⁺silicon layer.

9. The solar cell according to claim 8, further comprising a back-side metal layer formed on the back side of the silicon substrate.

10. The solar cell according to claim 9, wherein the silicon substrate further has a P⁺⁺ silicon section surrounding the embedded electrode.

11. The solar cell according to claim 9, wherein the back-side metal layer is made of aluminum.

12. The solar cell according to claim 9, wherein the embedded electrode is composed of a rectangular column portion and a cylindrical portion connected together.

13. The solar cell according to claim 9, wherein the embedded electrode is made of nickel, copper or silver.
